(19) United States
(12) Patent Application Publication
(10) Pub. No.: US 2015/0327403 A1
(43) Pub. Date: Nov. 12, 2015

(54) Power Module

(71) Applicant: Hitachi, Ltd., Chiyota-ku, Tokyo (JP)

(72) Inventors: Kazuaki NAOE, Tokyo (JP); Keishi SATO, Tokyo (JP)

(21) Appl. No.: 14/367,685

(22) PCT Filed: Nov. 28, 2012
(86) PCT No.: PCT/JP2012/080668

§ 371 Date: Jun. 23, 2014

(30) Foreign Application Priority Data
Jan. 10, 2012 (JP) 2012-001778
Jan. 16, 2012 (JP) 2012-005786

(51) Int. Cl. H05K 7/20

(52) U.S. Cl. CPC H05K 7/20509

(57) ABSTRACT

Provided is a power module that decreases thermal resistance while holding insulating reliability.

The present invention provides a power module including: a metal cooling plate; an insulating layer formed on the metal cooling plate, and made of an inorganic component that does not contain a resin component; a metal conductor plate stuck to the insulating layer through a resin layer; and a semiconductor element connected with the metal conductor plate by a joining member.

### TECHNICAL FIELD

The present invention relates to a power module.

### BACKGROUND ART

PTL 1 discloses a power module that includes: a wiring conductor plate having a semiconductor element arranged on one principal surface, a resin insulating layer arranged on the other principal surface of the wiring conductor plate, an inorganic layer arranged on a side opposite to the wiring conductor plate through the resin insulating layer, for being joined with the resin insulating layer, the inorganic insulating layer arranged on a side opposite to the resin insulating layer through the inorganic layer, and a metal heat dissipation member arranged on a side opposite to the inorganic layer through the inorganic insulating layer.

### CITATION LIST

### Patent Literature

PTL 1: JP 2010-258315 A

### SUMMARY OF INVENTION

### Technical Problem

In PTL 1, to improve insulating reliability of the power module, the insulating reliability is improved by a two-layer insulating layer formed of an insulating sheet made of an epoxy resin containing filler and an anodized aluminum layer formed on a metal heat dissipation member. However, there is a problem that thermal conductivities of a resin sheet made of organic components and a porous anodized aluminum layer are substantially lower than that of metal conductor plates or heat dissipation members, and thus a decrease in thermal resistance of the power module is difficult.

Therefore, an object of the present invention is to provide a power module that decreases the thermal resistance while holding the insulation reliability.

### Solution to Problem

To solve the above-described problem, a configuration described in claims is employed, for example. The present application includes a plurality of means for solving the problem, and one example thereof is a power module including: a metal cooling plate; an insulating layer formed on the metal cooling plate, and made of an inorganic component that does not contain a resin component; a metal conductor plate stuck to the insulating layer through a resin layer; and a semiconductor element connected with the metal conductor plate by a joining member.

Another example is a power module including: a metal cooling plate; an insulating layer formed on the metal cooling plate, and including an inorganic insulating portion made of an inorganic material, and an inorganic/organic hybrid insulating portion in which a void of an inorganic material contains an organic material; a metal conductor plate stuck to the insulating layer through a resin layer; and a semiconductor element connected with the metal conductor plate by a joining member.

### Advantageous Effects of Invention

According to the present invention, a power module that decreases the thermal resistance while holding the insulating reliability can be provided.

Problems other than the above description, configurations, and effects will become clear from the following description of embodiments.

### BRIEF DESCRIPTION OF DRAWINGS

FIG. 1 is a schematic diagram of a power module in a first embodiment.

FIG. 2 is a schematic diagram of a power module in a first modification.

FIG. 3 is a schematic diagram of a power module in a second modification.

FIG. 4 is a schematic diagram of a power module in a third modification.

FIG. 5 is a schematic diagram of a power module in a fourth modification.

FIG. 6 is a schematic diagram of a power module in a fifth modification.

FIG. 7 is an explanatory diagram of a configuration of an aerosol deposition device.

FIG. 8 is a schematic diagram of an electronic circuit substrate in a fourth embodiment.

FIG. 9(a) is a schematic diagram of an inorganic material 20 directly formed on a metal cooling plate 1.

FIG. 9(b) is a schematic diagram of an insulating layer 2 in which a void of the inorganic material 20 is impregnated with an organic material.

FIG. 10 is an explanatory diagram of a configuration of a particle compression breakdown test device.

FIG. 11 is a representative load change curve of when particles are compressed and broken down.

FIG. 12 is an image of a dense region 210 having no void in the inorganic material 20 by a scanning electron microscope.

FIG. 13 is an image of a region 220 having a void in which an organic material is impregnated in the inorganic material 20 by the scanning electron microscope.

### DESCRIPTION OF EMBODIMENTS

Hereinafter, embodiments will be described with reference to the drawings.

### First Embodiment

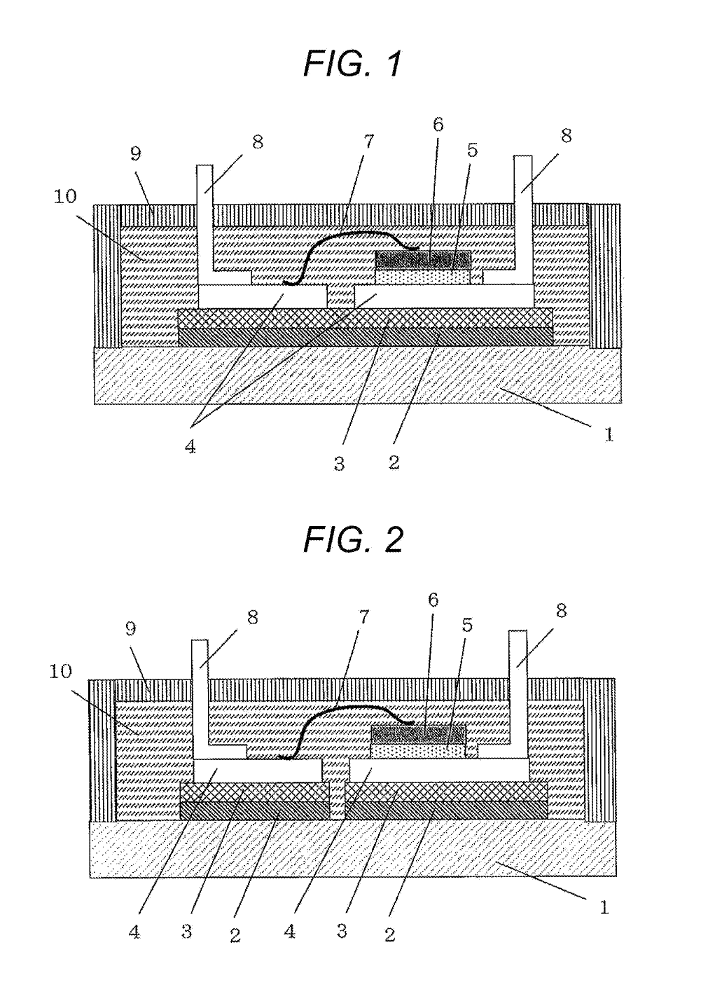

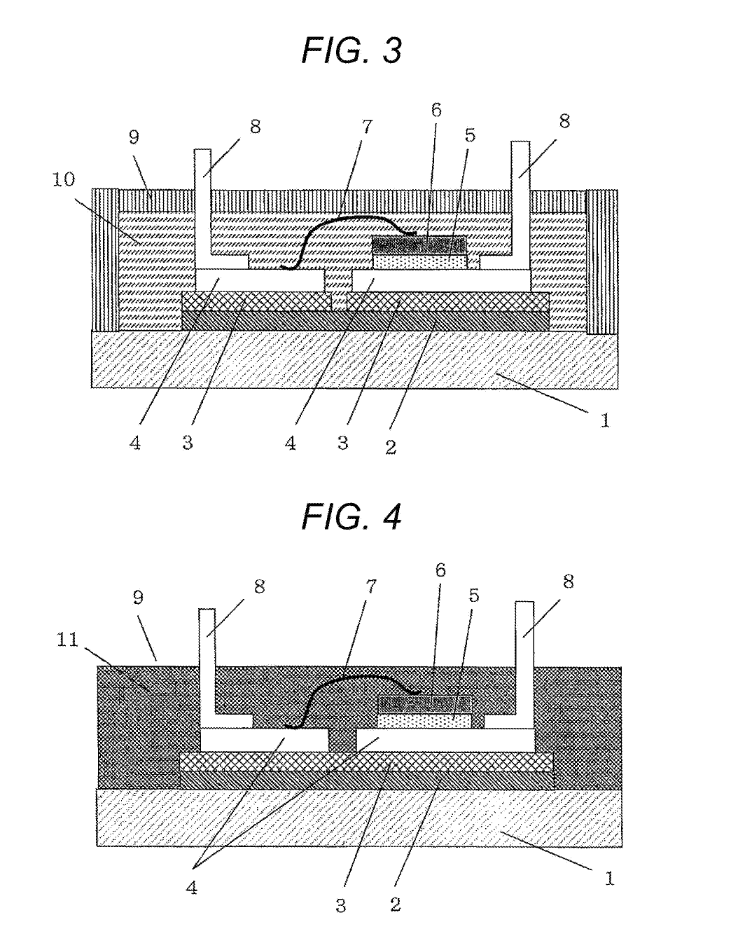

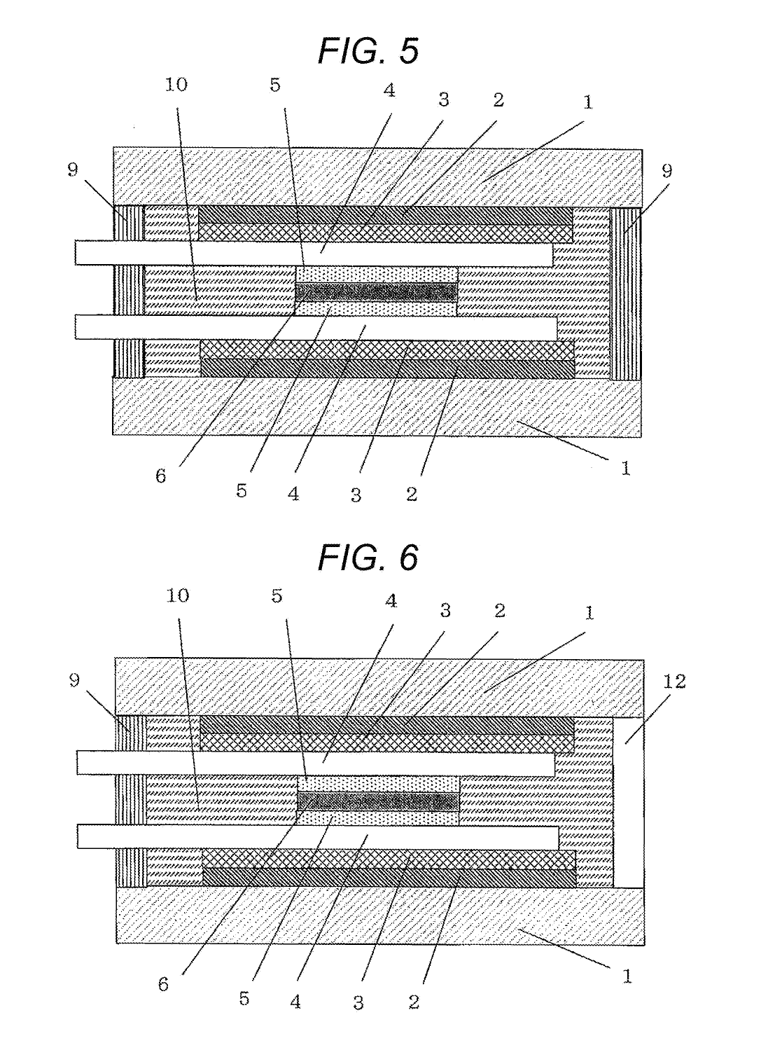

FIG. 1 illustrates a schematic diagram of a power module in the present embodiment. An insulating layer 2 that does not contain resin components and is formed of only inorganic components and insulates a metal cooling plate 1 and a semiconductor element 6 is directly formed on the metal cooling plate 1 that dissipates heat from the semiconductor element 6 without an adhesive layer. A metal fin for improving heat dissipation may be formed on one surface of the metal cooling plate 1, on which the insulating layer 2 is not formed. As an inorganic material used for the insulating layer 2, any conventional known material can be used as long as the material has electrical insulation properties. Examples of the material include Al₂O₃, AlN, TiO₂, Cr₂O₃, SiO₂, Y₂O₃, NiO, ZrO₂, SiC, TiC, WC, and the like. The insulating layer 2 may be a mixed film or a multilayer film of these materials. In terms of high thermal conductivity, SiC, AlN, Si₃N₄, Al₂O₃, or the like is desirable. Further, in terms of easy handling in the atmosphere and the manufacturing cost of the inorganic material, Al₂O₃ is most desirable. The insulating layer 2 may be divided and formed only on an adhesive portion of the metal conductor plate as illustrated in FIG. 2. Accordingly, use materials can be reduced, and the material cost can be reduced. The insulating layer 2 and the metal conductor plate 4 are stuck through a resin layer 3. The resin layer 3 may be divided and formed only on an adhesive portion of the metal conductor plate 4 as illustrated in FIG. 3. Accordingly, use materials can be reduced, and the material cost can be reduced. Examples of the resin include an epoxy resin, a phenol resin, a polyimide resin, a polyamide-imide resin, a silicon resin, and the like. As a method of applying the resin, any conventional known method, such as a screen printing method, an inkjet method, a roll coater method, a dispenser method, can be used. Further, the resin layer 3 may be formed such that a sheet resin is disposed between the insulating layer 2 and the metal conductor plate 4 and is stuck to them by thermal compression. By use of a sheet having a desired thickness, control of the thickness of the resin layer 3 becomes easier. Depending on the type of a resin to be used, the resin may need to be cured by means of heat, UV, or a laser in a state where the insulating layer 2 and the metal conductor plate 4 are stuck together after the resin is applied on the insulating layer 2 or the metal conductor plate 4. As the metal conductor plate 4, a metal plate made of an Al alloy, a Cu alloy, or the like can be used. A surface of the metal conductor plate 4 may be subjected to surface treatment, such as plating treatment for rust prevention, roughening treatment for improvement of adhesive strength with the resin layer 3, and oxidation treatment. The semiconductor element 6 is connected to the metal conductor plate 4 through a joining member 5. Examples of the semiconductor element 6 include a power semiconductor element, such as an IGBT, which converts a direct current into an alternating current by a switching operation, and a control circuit semiconductor element for controlling the power semiconductor element. Further, examples of the joining member 5 include solder, such as Pb—Sn based, Sn—Cu based, Sn—Ag—Cu based solder, metal, such as Ag, and a resin containing metal filler. An upper surface of the semiconductor element 6 and the metal conductor plate 4 are connected by a metal wire 7, such as Al. An external connection terminal 8 is connected to the metal conductor plate 4. A resin case 9 is stuck to a periphery of the metal cooling plate, and a sealing member 10, such as an insulating gel, is filled therein. Further, as illustrated in FIG. 4, the metal cooling plate except a cooling surface may be sealed with a mold resin 11. Accordingly, stress concentration to connection portions of module members is reduced, peeling of the connection portions can be suppressed, and temperature cycle reliability of a module operation is improved. The metal cooling plate 1 is not necessarily disposed only on one surface side of the semiconductor element 6, and may be provided on both surfaces of the semiconductor element 6, as illustrated in FIG. 5. Accordingly, a heat dissipation area is increased, compared with the case where the metal cooling plate 1 is provided only on one side of the semiconductor element 6, and thus the thermal resistance can be decreased. Further, as illustrated in FIG. 6, two metal cooling plates 1 may be joined by a metal plate 12, and may be formed into a can shape. Accordingly, even if the module is impregnated in a cooling medium, the cooling medium can be prevented from intruding into the module.

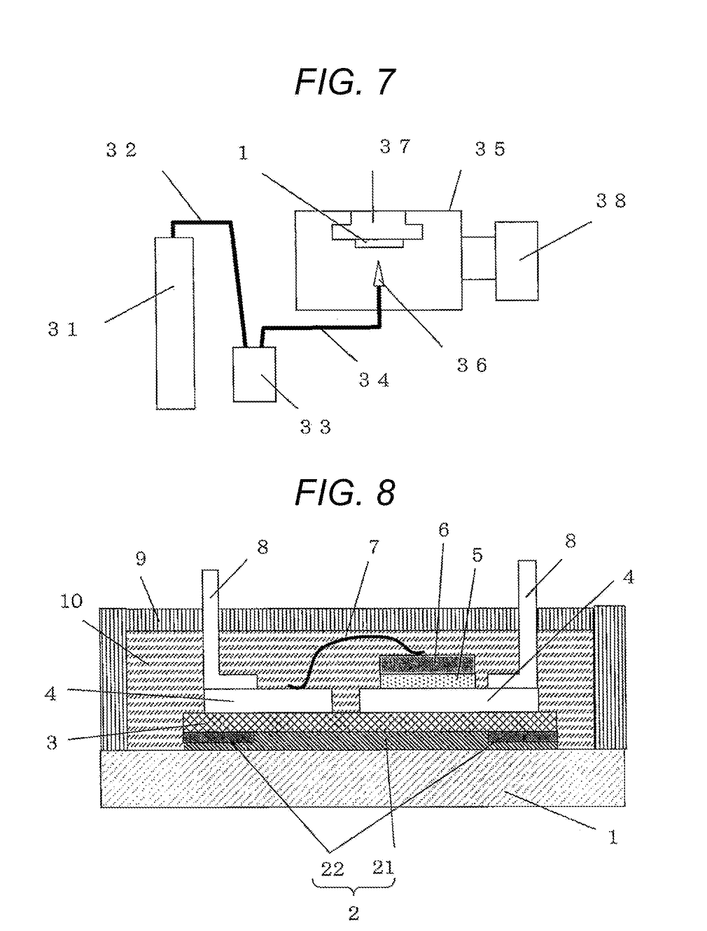

The insulating layer 2 is formed by an aerosol deposition method. An explanatory diagram of a configuration of an aerosol deposition device is illustrated in FIG. 7. A high-pressure gas bomb 31 is opened, and a carrier gas is introduced into an aerosol generator 33 through a gas conveying tube 32. Fine particles of an inorganic material, such as Al₂O₃, AlN, or Si₃N₄, which forms the insulating layer, are put in the aerosol generator 33, in advance. An average particle diameter of the fine particles is favorably 0.1 to 5 μm. When the fine particles are combined with the carrier gas, an aerosol containing the fine particles is generated. Examples of a usable carrier gas include an inert gas, such as argon, nitrogen, and helium. The metal cooling plate 1 is fixed to an XY stage 37 inside a vacuum chamber 35. When the vacuum chamber 35 is depressurized by a vacuum pump 38, a pressure difference is caused between the aerosol generator 33 into which the carrier gas is introduced and the vacuum chamber 35. By the pressure difference, the aerosol is sent to a nozzle 36 through a conveying tube 34, and is ejected through an opening of the nozzle toward the metal cooling plate 1 at a high speed. The fine particles in the aerosol collide with and coupled with the metal cooling plate 1. Further, the fine particles continuously collide, and are coupled with each other, so that the insulating layer 2 is formed. The insulating layer 2 is directly formed on the metal cooling plate 1, and a transition region in which configuration elements of the insulating layer 2 and of the metal cooling plate 1 are mutually diffused, and a reaction generation layer of the insulating layer 2 and the metal cooling plate 1 do not exist in an interface.

An anodized aluminum layer used in an insulating layer of a conventional structure has a porous structure in which a large number of fine holes of about 10 to 40 nm exists. These holes cause a decrease in the thermal conductivity of the insulating layer and a decrease in an insulating breakdown voltage. With the impregnation of the resin component, the holes are sealed, and the insulation properties are improved. However, the thermal conductivity of the resin is lower than that of the anodized aluminum, and thus improvement of the thermal conductivity of the insulating layer is limited. In the power module in the present embodiment, holes of about 10 to 40 nm do not exist in the insulating layer 2, which is formed on the metal cooling plate 1, and thus the insulating layer is a dense layer. Therefore, the insulating layer is superior to the porous anodized aluminum layer in the thermal conductivity. Because the insulating layer 2 is dense, the resin component of the resin layer 3 is not impregnated inside the insulating layer 2, and thus the thermal conductivity of the insulating layer 2 is not decreased. Further, regarding the insulation properties, when insulating breakdown voltages measured by a temporary pressure boost method are compared, while AL₂O₃ formed by anodized aluminum treatment has 10 to 20 V/μm, AL₂O₃ in the present embodiment has 50 to 400 V/μm. The insulating breakdown voltage of the insulating layer 2 in the present embodiment is 5 to 20 times higher than the insulating breakdown voltage of the insulating layer in the conventional structure. In the power module in the present embodiment, the thickness of the insulating layer 2 can be decreased while the insulation properties equivalent to the conventional structure is held, and thus the thermal resistance can be decreased. The insulating voltage necessary in the power module in the present embodiment is 2 to 15 kV, and from an insulating breakdown voltage value of the insulating layer 2, the necessary thickness for the insulating layer 2 is 5 to 300 μm.

In a power module, a current of about several to several hundred amperes flows in a metal conductor electrically connected with a semiconductor element. The metal conductor requires specific resistance and a thickness for decreasing the electrical resistance and a loss due to Joule heat. Further, forming the metal conductor thick has not only an effect to decrease the electrical resistance, but also an effect to allow heat generation of the semiconductor element to dissipate in the metal semiconductor and to make a heat flux small, and contributes to a decrease in the thermal resistance of the power module. In the power module, in terms of a use current and heat generation diffusion, use of a conductor having the thickness of several hundred μm to several mm and the specific resistance of 3 μΩ·cm or less equivalent to an Al alloy material is desirable.

Examples of a method of forming a metal conductor having the thickness of several hundred μm or more include a technique by means of metal layer formation by printing of a metal paste, a thermal spraying method, a cold spray method, or the like, and a technique by means of metal plate pasting with brazing filler metal or an adhesive. However, like the present embodiment, when the insulating layer made of only inorganic components and having the thickness of 5 to 300 μm is directly formed on the metal cooling plate, usable methods as the method of forming a metal conductor of a power module are limited.

When the metal conductor is formed by the printing of a metal paste, the electrical conduction of the metal conductor appears by physical contact among the metal particles, and thus formation of a metal conductor having specific resistance equivalent to the metal plate is difficult. Further, when the metal conductor is formed by the thermal spraying method, the specific resistance becomes larger than that of the metal plate due to pores introduced into the metal conductor at the formation, or oxidization of the metal particles. Meanwhile, by the cold spray method, formation of a dense metal conductor having the specific resistance equivalent to the metal plate and the thickness of about several mm is possible. However, with respect to the insulating layer having the thickness of 5 to 300 μm used in the present embodiment, peeling of the insulating layer and introduction of cracks are caused in the formation of the metal conductor, and thus the insulation properties of the insulating layer is reduced. When a Cu film having the thickness of 300 μm is formed on AL₂O₃ in the present embodiment by the cold spray method, the insulating breakdown voltage measured by a temporary pressure boost method is 0 to 30 V/μm, and the insulation properties are substantially reduced, compared with a case where the Cu film is not formed.

When the metal plate is pasted to the insulating layer, the specific resistance is smaller than that of the metal conductor formed by the printing or the thermal spraying method, and the thickness of several hundred μm to several mm can be realized by processing the metal plate to be pasted in advance. The metal plate is most desirable as a metal conductor of the power module. An example of a method of sticking the insulating layer and the metal plate includes active metal solder using an Ag—Ti based brazing filler metal. This technique requires a high temperature of about 800 to 1000° C. for sticking. However, when the insulating layer has the thickness of 5 to 300 μm like the present embodiment, a defect, such as a crack, is introduced to the insulating layer by heating of about 500° C. or more, and a decrease in the insulation properties and the thermal conductivity is caused. Therefore, as the method of sticking the insulating layer and the metal conductor plate, the active metal solder cannot be used. Meanwhile, if the insulating layer and the metal plate are stuck through a resin, such as an epoxy resin, they can be stuck at 200° C. or less in a case of heat curing, and a metal conductor can be formed without a decrease in the insulation properties.

As described above, when the insulating layer made of only inorganic components and having the thickness of 5 to 300 μm is directly formed on the metal cooling plate, usable methods as the method of forming a metal conductor of the power module are limited. Like the present embodiment, the insulating layer 2 and the metal conductor plate 4 are stuck through the resin layer 3, whereby a metal conductor required for the power module can be formed without a decrease in the insulation properties of the insulating layer 2.

### Second Embodiment

In the present embodiment, an example of a power module capable of further decreasing the thermal resistance, compared with the first embodiment, will be described. The present embodiment is different from the first embodiment in that an insulating layer 2 and a metal conductor plate 4 are joined through a resin layer 3 including metal particles as filler. Other configurations have the same functions as the above-described configurations illustrated in FIG. 1, with which the same reference signs are denoted, and thus description thereof is omitted.

In a power module in the present embodiment, insulation of 2 to 15 kV is possible according to the film thickness of the insulating layer 2 made of inorganic components, and thus the resin layer 3 intervening between the insulating layer 2 and the metal conductor plate 4 may be a conductive material. Therefore, metal particles can be contained in the resin layer 3 as filler. As the metal particles, Ag, Cu, Al, Au, or the like, having excellent thermal conductivity, is favorable. By use of these metal particles as the filler, a resin layer having the thermal conductivity of 5.0 W/mK or more can be used. Compared with a structure using ceramic particles, such as Al₂O₃, AlN, or SiO₂, as the filler, and a resin layer having the thermal conductivity of about 1.0 to 2.0 W/mK, the thermal conductivity of the resin layer 3 is improved in the power module of the present embodiment, and thus the thermal resistance can be further decreased, compared with the first embodiment.

### Third Embodiment

In the present embodiment, an example of a power module that improves adhesive strength between an insulating layer 2 and a metal conductor plate 4, and can suppress an increase in the thermal resistance even under a temperature cycle, compared with the first and second embodiment, will be described. The present embodiment is different from the first embodiment in that the thickness of a resin layer 3 is 5 μm or more. Other configurations have the same functions as the above-described configurations illustrated in FIG. 1, with which the same reference signs are denoted, and thus description thereof is omitted.

Operation reliability with respect to the temperature cycle according to the use environment is required for the power module. Under the temperature cycle, thermal stress caused by a difference between coefficients of thermal expansion of configuration members is generated. Due to the thermal stress, there is a possibility that peeling of an interface between configuration members is caused, and the thermal resistance of the power module is increased due to a decrease in a contact area in the interface. To suppress the peeling of the interface due to the thermal stress, the adhesive strength between configuration members needs to be improved.

The adhesive strength between the insulating layer 2 and the metal conductor plate 4 formed on a metal cooling plate 1 was evaluated by a Sebastian tension test. The metal conductor plate 4 made of Cu and having the thickness of 1 mm, and the insulating layer 2 made of Al₂O₃ having the film thickness of 10 μm are stuck using a resin paste containing Ag particles as the resin layer 3. While the tensile strength was 2 MPa when the thickness of the resin layer 3 was 3 μm, the tensile strength was improved to 10 MPa or more when the thickness of the resin layer 3 was 5 μm or more. When the insulating layer 2 made of only inorganic components and formed on the metal cooling plate 1 is stuck with the metal conductor plate 4, the adhesive strength between the insulating layer 2 and the metal conductor plate 4 can be improved by having the thickness of the resin layer 3 to be 5 μm or more. In the power module in the present embodiment, the adhesive strength between the insulating layer and the metal conductor plate can be improved, and thus the increase in the thermal resistance can be suppressed even under a temperature cycle.

### Fourth Embodiment

FIG. 8 illustrates a schematic diagram of a power module in the present embodiment. In the present embodiment, an example of a power module will be described, which can suppress an increase in the thermal conductivity even under a temperature cycle by configuring an insulating layer 2 from an inorganic insulating portion 21 and an inorganic/organic hybrid insulating portion 22, compared with the first to third embodiments. The increase in the thermal resistance can be suppressed even under a temperature cycle by causing a coefficient of thermal expansion to close to a resin layer 3 by the inorganic/organic hybrid insulating portion 22 and suppressing peeling of the resin layer 3 due to thermal stress while securing the thermal conductivity by the inorganic insulating portion 21. The embodiment is different from the first to third embodiments in that the insulating layer 2 is configured from the inorganic insulating portion 21 and the inorganic/organic hybrid insulating portion 22. Other configurations have the same functions as the above-described configurations illustrated in FIG. 1, with which the same reference signs are denoted, and thus description thereof is omitted.

In a power module in which only the inorganic insulating portion 21 exists in the insulating layer 2, which is directly formed on a metal cooling plate 1, when a metal conductor plate 4 is stuck to the insulating layer 2 through the resin layer 3, there are problems that peeling is developed in an interface between the insulating layer 2 and the resin layer 3 due to the temperature cycle, and the thermal resistance of the power module is increased due to a decrease in a contact area in the interface.

In the power module in the present embodiment, the inorganic insulating portion 21 made of only an inorganic material, and the inorganic/organic hybrid insulating portion 22 in which an organic material is impregnated in a void of an inorganic material exist in the insulating layer 2, and the metal conductor plate 4 is stuck through the resin layer 3. The inorganic/organic hybrid insulating portion 22 is formed in at least a part of the interface between the insulating layer 2 and the resin layer 3, whereby the peeling of the resin layer 3 due to the temperature cycle can be suppressed. Note that, in the present embodiment, the inorganic/organic hybrid insulating portion 22 may just be formed in at least a part of the interface between the insulating layer 2 and the resin layer 3, and the shape, size, the number of the inorganic/organic hybrid insulating portions 22 are not limited.

The inorganic insulating portion 21 made of only an inorganic material, and the inorganic/organic hybrid insulating portion 22 in which an organic material is impregnated in a void of an inorganic material exist in the insulating layer 2. As the organic material used for the insulating layer 2, any material can be used as long as the material has electrically insulation properties. Examples include an epoxy resin, a phenol resin, a fluorine-based resin, a silicon resin, a polyimide resin, a polyamide-imide resin, and the like. The organic material may contain inorganic particles, such as Al₂O₃, AlN, TiO₂, Cr₂O₃, SiO₂, Y₂O₃, NiO, ZrO₂, SiC, TiC, WC, or the like. By the containing of the inorganic particles, the coefficient of thermal expansion of the organic material is decreased. When the coefficient of thermal expansion of the organic material is larger than that of the inorganic material used for the insulating layer 2, and is smaller than that of the resin layer 3, the peeling of the resin layer 3 due to a temperature change can be effectively suppressed. For example, when Al₂O₃ (the coefficient of thermal expansion is 7×10⁻⁶/° C.) is used for the inorganic material, and epoxy (the coefficient of thermal expansion is 25×10⁻⁶ to 30×10⁻⁶/° C.) is used, an organic material having the coefficient of thermal expansion, which has been adjusted to about 10 to 20×10⁻⁶/° C., is desirable.

A position where the inorganic/organic hybrid insulating portion 22 is formed desirably includes an end portion of the resin layer 3 of an interface between the insulating layer 2 and the resin layer 3. The peeling of the resin layer 3 due to the temperature cycle is developed from the end portion. The inorganic/organic hybrid insulating portion 22 having a higher coefficient of thermal expansion than the inorganic insulating portion 21 is formed on the end portion of the resin layer 3, and a difference between the coefficients of thermal expansion of the inorganic/organic hybrid insulating portion 22 and the resin layer 3 is made smaller, whereby the thermal stress can be decreased, and the peeling of the resin layer 3 due to the temperature cycle can be effectively suppressed.

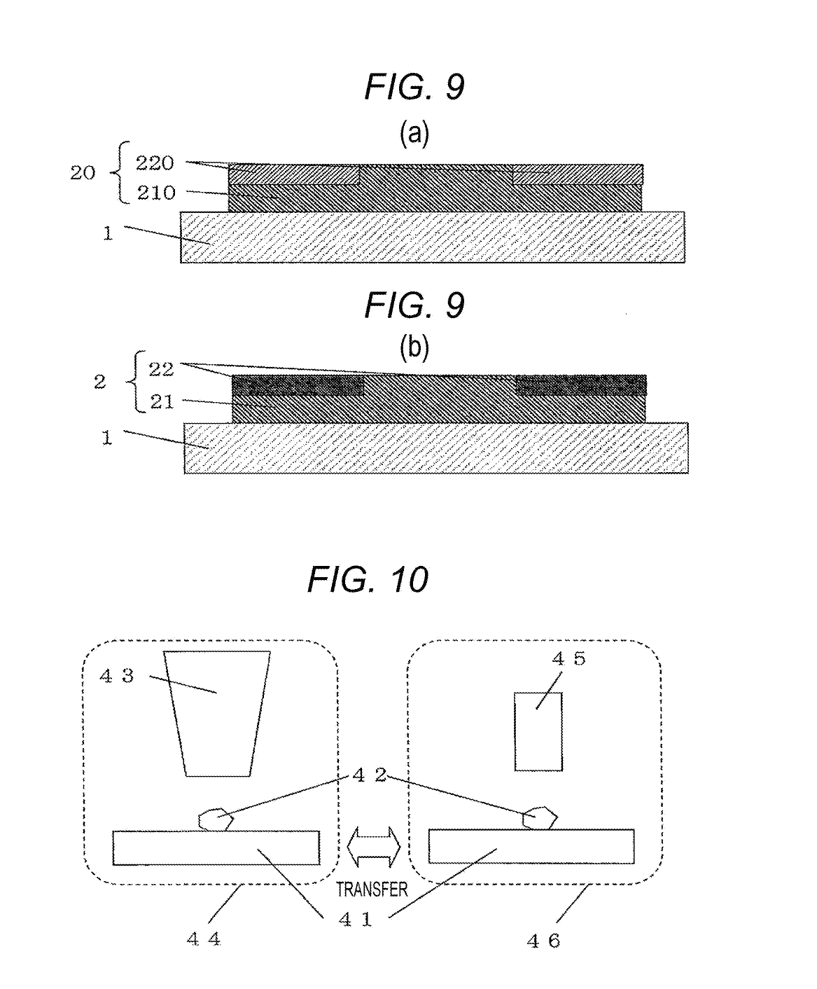

A method of manufacturing the insulating layer 2 includes a step of directly forming the inorganic material 20 on the metal cooling plate 1 by an aerosol deposition method illustrated in FIG. 9(a), and a step of impregnating the organic material in a void of the inorganic material 20 illustrated in FIG. 9(b). A region 210 having no void and a region 220 having a void exist in the inorganic material 20, and after the impregnation of the organic material, the region made of only the inorganic material and having no void in which the organic material is impregnated functions as the inorganic insulating portion 21, and the region having a void in which the organic material is impregnated functions as the inorganic/organic hybrid insulating portion 22.

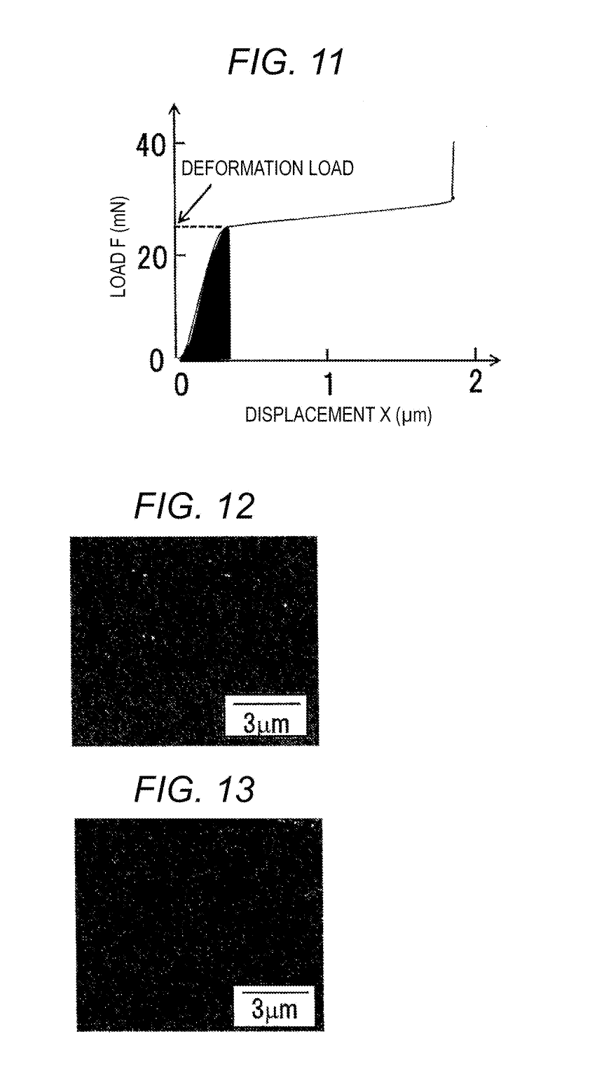

First, a process of directly forming the inorganic material 20 on the metal cooling plate 1 by an aerosol deposition method will be described. The region 220 having a void in which the organic material is impregnated and the dense region 210 having no void are formed in the inorganic material 20. Existence of the void of the inorganic material 20 can be controlled by changing the particles to be put in an aerosol generator 33 of an aerosol deposition device. For selection of the particles according to the existence of the void, evaluation of deformation energy of the particles as described below is effective. A method of evaluating the deformation energy will be described using Al₂O₃ particles as an example. A compression breakdown test of the particles is used for the evaluation of the deformation energy. A schematic diagram of a test device is illustrated in FIG. 10. With a stage 41, particles 42 placed on the stage 41 can be transferred between a place 44 where a displacement amount of the particle 42 of when test force is applied by a pressure penetrator 43 is measured, and a place 46 where the shape and the diameter of the particle 42 is measured by an optical microscope 45. FIG. 11 illustrates a representative load deformation curve of when the particles are compressed and broken down in conditions of using a flat pressure penetrator having the diameter of 20 μm, the test force of 100 mN, and a load speed of 3.87 mN/sec, using the test device. The filled area illustrated in FIG. 11 corresponds to elastic energy accumulated in the particles before deformation. The deformation energy is defined by subtracting the elastic energy by the particle volume obtained from the particle diameter measured by the optical microscope 45 installed at the stage before the test, and was used in the particle evaluation.

Commercially available Al₂O₃ powder is used for the evaluation of the deformation energy of the particles. The used types of the Al₂O₃ powder are AMS-5020F, AKP-20, and AA-1.5. The deformation energy of seven particles of each powder was measured, and average deformation energy was evaluated. A result is illustrated in Table 1. When a film was formed using Cu for the metal cooling plate 1, N₂ for the carrier gas, and a nozzle 36 having a gas flow rate of 2 L/min, an opening portion of 10 mm×0.4 mm, the structure of the inorganic material 20 obtained from a difference of the average deformation energy is changed. FIGS. 12 and 13 illustrate the structure of the inorganic material 20 by an image of a cross section of the inorganic material captured using a field emission scanning electron microscope. The lower side of the image is an interface side with the Cu plate, and the upper side is a surface side of the inorganic material 20. When AMS-5020F having the average deformation energy of 7.3×10⁻² nJ/μm³ is used, the dense inorganic material 20 having no void can be formed, as illustrated in FIG. 11. Meanwhile, when AKP-20 having the average deformation energy is 1.2×10⁻¹ nJ/μm³ is used, the inorganic material 20 in which a void having the width of about 0.5 μm or less in a direction parallel with the Cu plate interface and the length of about 1 to 20 μm is formed at intervals of about 1 to 3 μm in the thickness direction of the inorganic material 20 can be formed, as illustrated in FIG. 12. However, when AA-1.5 having the deformation energy of 3.3×10⁻¹ nJ/μm³ is used, the inorganic material having the thickness of about 2 μm or more was not able to be formed. When the insulating layer 2 requires 2 μm or more, AA-1.5 having the deformation energy of 3.3×10⁻¹ nJ/μm³ cannot be used.

Further, particles that has lower deformation energy has higher film forming efficiency with respect to the metal plate 1. The film forming efficiency is a ratio of the weight of the inorganic material 20 formed on the metal plate 1 to the particle weight of the particles that have collided with the metal plate 1, and which means the inorganic material 20 having the same volume can be formed with a smaller number of particles as the film forming efficiency becomes higher. The table indicates the relationship between the deformation energy and a relative value of the film forming efficiency. The inorganic material 20 can be formed at a lower cost if particles having lower deformation energy, that is, AMS-5020F are used.

TABLE 1

| | Average | Film forming |
|---|---|---|
| | deformation energy | efficiency |
| Type of powder | (nJ/μm³) | (relative value) |
| AMS-5020F | 7.3 × 10⁻² | 2.1 × 10¹ |
| AKP-20 | 1.2 × 10⁻¹ | 9.3 |
| AA-1.5 | 3.3 × 10⁻¹ | 1.0 |

In manufacturing of the power module in the present embodiment, first, the dense region 210 having no void is formed on the metal cooling plate 1 using the Al₂O₃ powder that can form the dense inorganic material having no void, that is, AMS-5020F. Next, the region 220 having a void in which the organic material is impregnated is formed on a part of the dense region 210 having no void, using the Al₂O₃ powder that can form an inorganic material having a void, for example, AKP-20. At this time, by moving the XY stage 37 and changing a relative position of the nozzle 36 and the metal plate 1, the shapes and the positions of formation of the dense region 210 having no void and of the region 220 having a void in which the organic material is impregnated can be controlled.

Next, a process of impregnating the organic material, that is, a process of impregnating the epoxy resin in the void of the inorganic material 20, will be described. When the epoxy resin is dropped on the end portion and the surface of the inorganic material 20, the void of the region 220 having the void in which the organic material is impregnated is impregnated with the epoxy resin. After the epoxy resin is applied, the inorganic material 20 is left for 5 to 10 minutes. Then, an extra epoxy resin on the end portion and the surface is removed by a squeegee or the like. The inorganic material 20 is held for about 60 minutes at 150° C. in accordance with a curing condition of the epoxy resin, and the epoxy resin is cured. Finally, the epoxy resin remained on the end portion and the surface of the inorganic material 20 and cured is removed by a sandpaper, or the like.

According to the above method, the insulating layer 2 including the inorganic insulating portion 21 made of only an inorganic material and having no void in which the organic material is impregnated, and the inorganic/organic hybrid insulating portion 22 having a void of an inorganic material, in which the organic material is impregnated, can be directly formed on the metal plate 1. Note that, in the present embodiment, the inorganic insulating portion 21 made of only an inorganic material and the inorganic/organic hybrid insulating portion 22 having a void of an inorganic material, in which an organic material is impregnated, may just exist in the insulating layer 2, and the inorganic/organic hybrid insulating portion 22 may just be formed on at least a part of the interface between the insulating layer 2 and the resin layer 3, and the shape, size, and the number of the inorganic/organic hybrid insulating portions 22, and the like are not limited.

A temperature cycle test was conducted with the power module in the present embodiment. An inorganic material made of Al₂O₃ having the thickness of 50 μm was formed on a Cu plate by an aerosol deposition method. Next, the insulating layer including the inorganic insulating portion and inorganic/organic hybrid insulating portion were formed by impregnating the void with an epoxy resin. Further, the insulating layer and a Cu plate having the thickness of 1 mm were stuck using the epoxy resin containing the Al₂O₃ particles as the resin layer. Further, as a conventional structure, Al₂O₃ having the thickness of 50 μm, in which only an inorganic insulating portion exists, was formed on a Cu plate by the aerosol deposition method, and a power module in which the Al₂O₃ and a Cu plate having the thickness of 1 mm are stuck was formed using the epoxy resin containing the Al₂O₃ particles. A temperature cycle condition was such that the power module was held for 30 minutes where the temperature was −40° C., and then the temperature was raised to 125° C. and the power module was held for 30 minutes, and these processes were repeated by 100 cycles.

After the temperature cycle test, the interface between the insulating layer and the resin layer was observed by an electronic scan-type high-speed ultrasonic diagnosis device, and existence of peeling was confirmed. While in the conventional power module in which only the inorganic insulating portion exists in the insulating layer, the peeling was caused in the interface between the insulating layer and the resin layer, in the power module of the present embodiment, in which the inorganic insulating portion made of only an inorganic material and the inorganic/organic hybrid insulating portion having a void of an inorganic material, in which an organic material is impregnated, exist in the insulating layer, the peeling was not caused in the interface between the insulating layer and the resin layer, and it was confirmed that an increase in the thermal resistance under the temperature cycle can be suppressed, compared with the conventional structure.

Note that the present invention is not limited to the above embodiments, and includes various modifications. For example, the above embodiments have been described in detail for explaining the invention in a way easy to understand, and are not necessarily limited to ones including all of the described configurations. Further, a part of a configuration of a certain embodiment can be replaced with a configuration of another embodiment, or a configuration of another embodiment can be added to a configuration of a certain embodiment. Further, another configuration can be added to/deleted from/replaced with a part of a configuration of each embodiment.

### REFERENCE SIGNS LIST

1 metal cooling plate
2 insulating layer
3 resin layer
4 metal conductor plate
5 joining member
6 semiconductor element
7 metal wire
8 external connection terminal
9 resin case
10 sealing member
11 mold resin
21 inorganic insulating portion
22 inorganic/organic hybrid insulating portion
20 inorganic material
210 dense region having no void
220 region having a void in which an organic material is
impregnated
31 high-pressure gas bomb
32 and 34 conveying tube
33 aerosol generator
35 vacuum chamber
36 nozzle
37 XY stage
38 vacuum pump
41 stage
42 particles
43 pressure penetrator
44 place where a displacement amount of a particle is measured
45 optical microscope
46 place where a shape and a diameter of a particle is measured

1. A power module comprising:
a metal cooling plate;
an insulating layer formed on the metal cooling plate, and made of an inorganic component that does not contain a resin component;
a metal conductor plate stuck to the insulating layer through a resin layer; and
a semiconductor element connected with the metal conductor plate by a joining member.

2. The power module according to claim 1,
wherein the insulating layer, the metal conductor plate, and the semiconductor element are sealed by a resin.

3. The power module according to claim 1,
wherein the metal cooling plate is provided on both surface sides of the semiconductor element.

4. The power module according to claim 1,
wherein a thickness of the insulating layer is 5 to 300 μm.

5. The power module according to claim 1, wherein the insulating layer contains Al₂O₃.

6. The power module according to claim 1, wherein the resin layer contains metal particles.

7. The power module according to claim 1,
wherein a thickness of the resin layer is 5 μm or more.

8. A power module comprising:
a metal cooling plate;
an insulating layer formed on the metal cooling plate, and including an inorganic insulating portion made of an inorganic material, and an inorganic/organic hybrid insulating portion in which a void of an inorganic material contains an organic material;
a metal conductor plate stuck to the insulating layer through a resin layer; and
a semiconductor element connected with the metal conductor plate by a joining member.

9. The power module according to claim 8,
wherein at least a part of an end portion of the insulating layer is formed of the inorganic/organic insulating portion.

10. The power module according to claim 8,
wherein the organic material contained in the inorganic/organic insulating portion contains inorganic particles.
